(19) United States
(12) Patent Application Publication
(10) Pub. No.: US 2020/0214154 A1
(43) Pub. Date: Jul. 2, 2020

(54) SCREEN PROTECTOR AND METHOD FOR APPLYING THE SAME

(71) Applicant: SHENZHEN KANGCHENGTAI INDUSTRIAL CO., LTD., Shenzhen (CN)

(72) Inventor: Zhaofei Liang, Shenzhen (CN)

(21) Appl. No.: 16/247,723

(22) Filed: Jan. 15, 2019

(30) Foreign Application Priority Data
Dec. 28, 2018 (CN) 201811623353.1

(51) Int. Cl. H05K 5/03; G06F 1/16; B32B 27/40; B32B 27/36; H05K 5/00

(52) U.S. Cl. CPC H05K 5/03; G06F 1/1626; B32B 27/40; B32B 2307/412; H05K 5/0017; B32B 2307/584; B32B 27/36

(57) ABSTRACT

The present application provides a screen protector and a method for applying a screen protector, including a release film, a hydrogel film, a silicone protective film, and a release liner sequentially stacked, an edge of the release film is provided with positioning lug, the silicone protective film is provided with a die-cutting line, an edge of the first part protrudes outwards to form a first lug, and an edge of the second part protrudes outwards to form a second lug. The silicone protective film is divided into two parts, tearing off the first part and tearing off the second part are independent from each other, avoiding the movement of the screen protector due to the large amplitude of the tearing film during the tearing process, the deviation occurring during the applying process of the screen protector is avoided, and the applying efficiency of the screen protector is improved.

### CROSS REFERENCE

This application claims priority to Chinese Patent Application No. 201811623353.1, filed with the Chinese Patent Office on Dec. 28, 2018 and entitled “screen protector and method for applying the same”, which is incorporated herein by reference in its entirety.

### TECHNICAL FIELD

The present application relates to the technical field of screen protector of electronic products, and more particularly to a screen protector and a method for applying the same.

### BACKGROUND

Electronic products such as cell phone, tablet and the like have become an indispensable part of people's daily lives, and with the continuous development of technology, the performance and appearance of the electronic products are constantly upgraded. In order to better protect the electronic products, such as, cell phone, people usually stick a screen protector on the screen of the electronic product to prevent the screen of the electronic product from being scratched or polluted.

However, the screen protectors, such as a screen protector for cell phone, still have some shortcomings, such as, during the applying process, the screen protector may move during operation, which also causes a deviation in the final position of the screen protector.

### SUMMARY

An object of the present application is to provide a screen protector and a method for applying a screen protector, in order to solve the technical problem that the existing screen protector is easy to move and cause a deviation at a position where the screen protector is applied to during the applying operation of the screen protector.

In order to solve the above object, the present application is achieved adopting the following technical solutions: a screen protector, including: a release film, a hydrogel film, a silicone protective film, and a release liner sequentially stacked, an edge of the release film is provided with positioning lug configured for positioning, the silicone protective film is provided with a die-cutting line dividing the silicone protective film into a first part and a second part, an edge of the first part protrudes outwards to form a first lug configured for tearing off the first part, and an edge of the second part protrudes outwards to form a second lug configured for tearing off the second part.

Further, a top of the first part protrudes outwards to form the first lug, and a bottom of the second part protrudes outwards to form the second lug.

Further, the release liner corresponding to the position of the first lug protrudes outwards to form a third lug; the release liner corresponding to the position of the second lug protrudes outwards to form a fourth lug.

Further, the number of the positioning lugs is two, and the two positioning lugs are respectively disposed at opposite ends of the release film, and each of the positioning lugs is provided with at least one positioning hole for positioning.

The present application further provides a method for applying a screen protector, using the screen protector above, including:

S01, cleaning a screen of the electronic product to be applied, and placing the electronic product to be applied into a positioning frame;

S02, tearing off the release liner;

S03, applying the silicone protective film to the screen of the electronic product to be applied by positioning the positioning lug with the positioning frame;

S04, tearing off the first part via the first lug of the first part;

S05, using a scraping card to forcefully scrape the first part until a portion of the hydrogel film corresponding to the first part sticks to a planar portion of the screen;

S06, tearing off the second part via the second lug of the second part, and using a scraping card to forcefully scrape the second part until a portion of the hydrogel film corresponding to the second part sticks to a planar portion of the screen;

S07, using the scraping card to scrape outwardly along a curved edge of the screen until two lateral edges of the hydrogel film stick to two lateral edges of the screen;

S08, tearing off the release film via the positioning lug of the release film, and smoothing two lateral edges of the screen.

Further, the step of cleaning the screen of the electronic product to be applied further including:

wiping the screen of the electronic product to be applied with an alcohol;

wiping the screen of the electronic product to be applied with a non-woven fabric.

Further, the step of tearing off the first part via the first lug of the first part further including:

uncovering the first part, and then pulling the first lug to tear off an end of the first part adjacent to the second part such that the end of the first part adjacent to the second part is separated from the hydrogel film, and abutting the portion of hydrogel film corresponding to the first part onto the screen.

Further, the step of tearing off the second part via the second lug of the second part further including:

uncovering the second part, and then pulling the second lug to tear off an end of the second part adjacent to the first part such that the end of the second part adjacent to the first part is separated from the hydrogel film, and abutting the portion of hydrogel film corresponding to the second part onto the screen.

Further, in the step S05 and the step S07, a bottom of the scraping card is placed obliquely relative to the screen, and an initial position of the scraping card during scarping is located on the die-cutting line.

Further, an oblique angle between the bottom of the scraping card and the screen is in the range of 45° to 60°.

The screen protector provided by the present application has the following beneficial effects: compared with the prior art, the present application protrudes outwards to form the positioning lug at the edge of the release film, therefore the screen protector can be better positioned to avoid deviation during the applying process; the silicone protective film is provided with the die-cutting line to divide the silicone protective film into the first part and the second part, and the first part protrudes outwards to form the first lug, the second part protrudes outwards to form the second lug, such that in the process of tearing off the screen protector, the first part of the silicone protective film can be torn off via the first lug, the second part of the silicone protective film can be torn off via the second part; the silicone protective film is divided into two parts, such that tearing off the first part and tearing off the second part are independent from each other, thereby avoiding the movement of the screen protector due to the large amplitude of the tearing film during the tearing process, thereby avoiding the deviation occurring during the applying process of the screen protector, and improving the applying efficiency of the screen protector.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a structural exploded view of a screen protector according to an embodiment of the present application;

FIG. 2 is a structural schematic view of a silicone protective film of a screen protector according to an embodiment of the present application;

FIG. 3 is a structural schematic view of another silicone protective film of a screen protector according to an embodiment of the present application;

FIG. 4 is a structural schematic view of a release film according to an embodiment of the present application;

FIG. 5 is a structural schematic view of a positioning frame according to an embodiment of the present application;

FIG. 6 is a cross-section view taken from line A-A in FIG. 5 according to an embodiment of the present application;

FIG. 7 is a flow chart of steps of a method for applying a screen protector according to an embodiment of the present application.

In the drawings, the reference numerals are as follow:

1-release film; 11-positioning lug; 110-positioning hole;

2-hydrogel film;

3-silicone protective film; 31-first part; 311-first lug; 32-second part; 321-second lug; 33-die-cutting line;

4-release liner; 41-third lug; 42-fourth lug;

5-positioning frame; 51-positioning post.

### DETAILED DESCRIPTION OF THE EMBODIMENTS

In order to make the purpose, the technical solution and the advantages of the present application be clearer and more understandable, the present application will be further described in detail below with reference to accompanying figures and embodiments. It should be understood that the specific embodiments described herein are merely intended to illustrate but not to limit the present application.

It is noted that when a component is referred to as being “fixed to” or “disposed at” another component, it can be directly or indirectly on another component. When a component is referred to as being “connected to” another component, it can be directly or indirectly connected to another component. Directions or location relationships indicated by terms such as “length”, “width”, “up”, “down”, “front”, “rear”, “left”, “right”, “vertical”, “horizontal”, “top”, “bottom”, “inside”, “outside”, and so on are the directions or location relationships shown in the accompanying figures, which are only intended to describe the present application conveniently and simplify the description, but not to indicate or imply that an indicated device or component must have specific locations or be constructed and manipulated according to specific locations; therefore, these terms shouldn't be considered as any limitation to the present application. Terms “the first” and “the second” are only used in describe purposes, and should not be considered as indicating or implying any relative importance, or impliedly indicating the number of indicated technical features. As such, technical feature(s) restricted by “the first” or “the second” can explicitly or impliedly comprise one or more such technical feature(s). In the description of the present application, “a plurality of” means two or more, unless there is additional explicit and specific limitation.

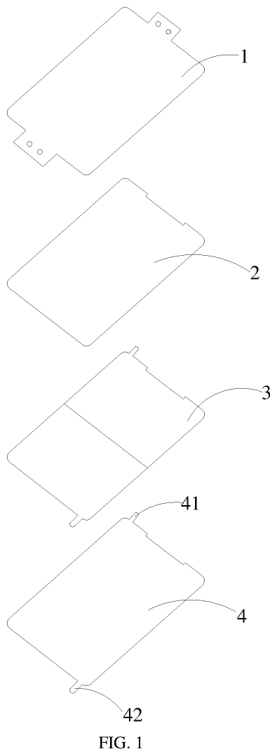

As shown in FIG. 1 to FIG. 4, the present embodiment provides a screen protector, including: a release film 1, a hydrogel film 2, a silicone protective film 3, and a release liner 4. The release film 1, the hydrogel film 2, the silicone protective film 3, and the release liner 4 are sequentially stacked, an edge of the release film 1 is provided with positioning lug 11, the silicone protective film 3 is provided with a die-cutting line 33 dividing the silicone protective film 3 into a first part 31 and a second part 32, an edge of the first part 31 protrudes outwards to form a first lug 311, and an edge of the second part 32 protrudes outwards to form a second lug 321. Thus, the edge of the release film 1 protrudes outwards to form a positioning lug 11, thereby the screen protector can be better positioned to avoid deviation during the applying process. The silicone protective film 3 is provided with a die-cutting line 33 to divide the silicone protective film 3 into a first part 31 and a second part 32, and the first part 31 protrudes outwards to form a first lug 311, the second part 32 protrudes outwards to form a second lug 321, such that in the process of tearing off the screen protector, the first part 31 of the silicone protective film 3 can be torn off via the first lug 311, the second part 32 of the silicone protective film 3 can be torn off via the second part 321; the silicone protective film 3 is divided into two parts, such that tearing off the first part 31 and tearing off the second part 32 are independent from each other, thereby avoiding the movement of the screen protector due to the large amplitude of the tearing film during the tearing process, thereby avoiding the deviation occurring during the applying process of the screen protector, and improving the applying efficiency of the screen protector.

Preferably, the release film 1 is a Poly-Ethylene Terephthalate (PET) release film, and the hydrogel film 2 is a Thermoplastic Polyurethanes (TPU) hydrogel film. In the present embodiment, the release film 1 may be a release film of other material, and the hydrogel film 2 may be a hydrogel film of other material, which is not limited herein.

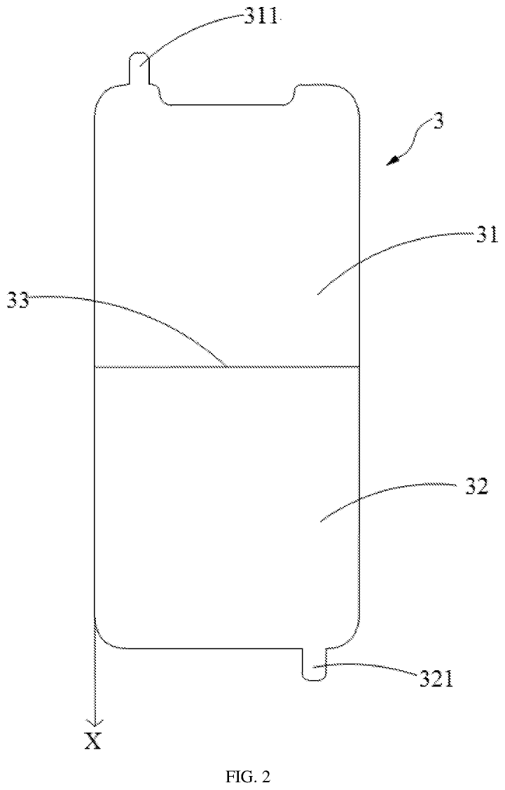

Further, as shown in FIG. 2, as a specific embodiment of the screen protector provided by the present application, a top end of the first part 31 protrudes outwards to form a first lug 311, and a bottom end of the second part 32 protrudes outwards to form a second lug 321. Thus, by disposing the first lug 311 at the top end of the first part 31, it is convenient to quickly tear off the first part 31 to realize separation of the first part 31 from the hydrogel film 2; and by disposing the second lug 321 at bottom end of the second part 32, it is convenient to quickly tear off the second part 32 to realize separation of the second part 32 from the hydrogel film 2, the tearing operation efficiency is improved. Further, the first lug 311 is disposed at left side of the top end of the first part 31, the second lug 321 is disposed at right side of the bottom of the second part 32, the first lug 311 and the second lug 321 are arranged in such way, which can be matched with left and right hand structure of the human body, that is, fast tearing off the first part 31 or the second part 32 can be achieved by the left or right hand of the human body.

In the present embodiment, please refer to FIG. 2, the top end direction of the first part and the bottom end direction of the second part are both the X direction in FIG. 2.

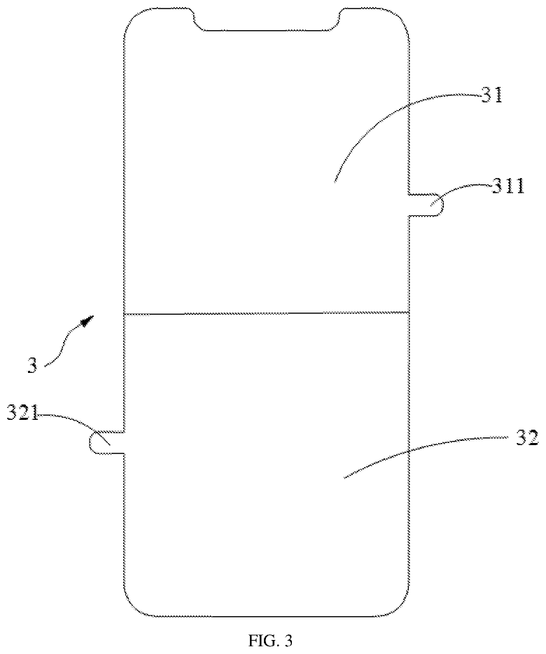

Further, as shown in FIG. 3, as a specific embodiment of the screen protector provided by the present application, the right end of the first part 31 extend outward to form a first lug 311, and the left end of the second part 32 extend outward to form a second lug 321. Thus, by disposing the first lug 311 at the right end of the first part 31, and by disposing the second lug 321 at the left end of the second part 32, so that the first part 31 and the second part 32 can be torn off to realize separation of the first part 31and the second part 32 from the hydrogel film 2. In addition, in the embodiment, the first lug 311 can also be disposed at left side of the first part 31, and the second lug 321 can also be disposed at right side of the second part 32, the first lug 311 is disposed at corners of the first part 31, and the second lugs 321 is disposed at corners of the second part 32, etc., which is not limited herein.

Further, in the embodiment, the length ratio of the first part 31 and the second part 32 of the silicone protective film 3 ranges from 1:2 to 1:1. At this time, the length of the second part 32 is slightly larger than the first part to facilitate positioning of the hydrogel film 2 at the time of applying the screen protector to the electronic products, while reducing bubbles in the hydrogel film 2. In addition, the length ratio of the first part 31 and the second part 32 may be set to be other, which is not limited herein.

In the embodiment, on the one hand, the first part 31 and the second part 32 can support the hydrogel film 2, so that the screen protector is not bended by the self-weight and convenient for attaching and positioning, on another hand, the first part 31 and the second part 32 are repeatedly stuck to the screen of the electronic product, thereby the cleaning of the static electricity and dust on the surface of the electronic product screen is achieved, and facilitate for the subsequent applying process.

Further, as shown in FIG. 1, as a specific embodiment of the screen protector provided by the present application, the release liner 4 further includes a third lug 41 and a fourth lug 42, the third lug 41 is disposed opposite the position of the first lug 311, and the fourth lug 42 is disposed opposite the position of the second lug 321. Thus, by disposing the third lug 41 and the fourth lug 42, the first lug 311 and the second lug 321 of the silicone protective film 3 can be protected on the one hand, and on the other hand, during the tearing process, it is also convenient for tearing off the release liner 4 via the third lug 41 or the fourth lug 42 to improve the efficiency of tearing off the screen protector.

Preferably, the first lug 311, the second lug 321, the third lug 41 and the fourth lug 42 are all in arched or semi-circular to prevent them from scratching the screen of the electronic product, in addition, in the embodiment, according to the actual situation and specific needs, the above-mentioned lugs may also be arranged in other shapes, which are not limited herein.

Preferably, the first lug 311 and the second lug 321 are also disposed on the silicone protective film 3 by adhering, and the third lug 41 and the fourth lug 42 can also be disposed on the silicone protective film 3 by adhering or printing, or by other means, which is not limited herein.

Preferably, the release film 1 is a transparent member, so that the process of tearing off the screen protector can be seen more intuitive and clear, and the efficiency of the tearing off the screen protector is greatly improved. In addition, in the embodiment, according to actual conditions and specific needs, the above release film 1 can also be set as a translucent member or the like, which is not limited herein.

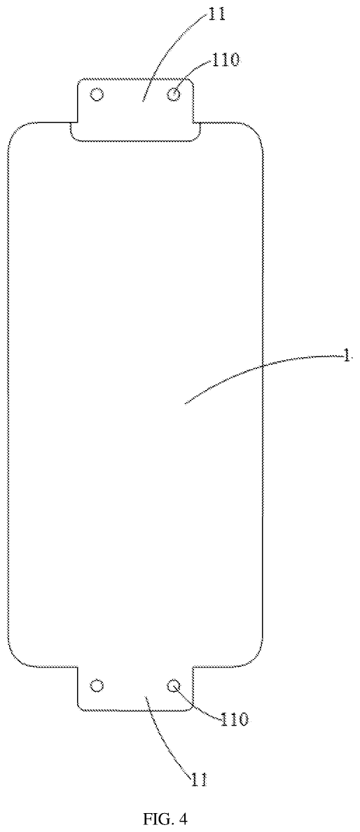

Further, as shown in FIG. 4, as an embodiment of the screen protector provided by the present application, the number of the positioning lugs 11 is two, and two positioning lugs 11 are respectively disposed at two ends of the release film 1, and each of the positioning lugs 11 is provided with at least one positioning hole 110. Thus, the two positioning lugs 11 are respectively disposed at opposite ends of the release film 1, and each of the positioning lugs 11 is provided with positioning hole 110, thereby a better positioning of the screen protector can be achieved. Preferably, in the embodiment, each of the positioning lugs 11 is provided with two positioning holes 110, and each of the positioning holes 110 are respectively disposed at two sides of the positioning lug 11, thereby a better positioning of the screen protector can be stably achieved by four points fixing, and providing a guarantee for subsequent applying the screen protector to the electronic product. In addition, in the embodiment, the number of above positioning holes can be may be other, which is not limited herein.

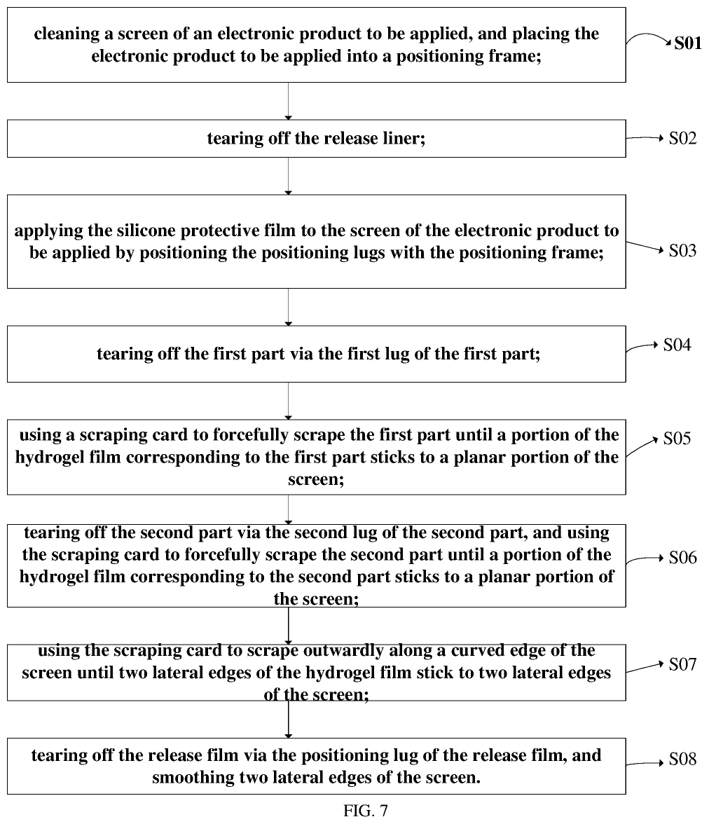

In the present application, a method for applying a screen protector is also provided. Please refer to FIG. 7, the method uses the above screen protector, and specifically includes the following steps:

S01, cleaning a screen of the electronic product to be applied, and placing the electronic product to be applied into a positioning frame;

S02, tearing off the release liner 4;

S03, applying the silicone protective film 3 to the screen of the electronic product to be applied by positioning the positioning lug with the positioning frame;

S04, tearing off the first part 31 via the first lug 311 of the first part 31;

S05, using a scraping card to forcefully scrape the first part 31 until a portion of the hydrogel film 2 corresponding to the first part 31 sticks to a planar portion of the screen;

S06, tearing off the second part 32 via the second lug 321 of the second part 32, and using a scraping card to forcefully scrape the second part 32 until a portion of the hydrogel film 2 corresponding to the second part 32 sticks to a planar portion of the screen;

S07, using the scraping card to scrape outwardly along a curved edge of the screen until two lateral edges of the hydrogel film stick to two lateral edges of the screen;

S08, tearing off the release film 1 via the positioning lug 11 of the release film 1, and smoothing two lateral edges of the screen.

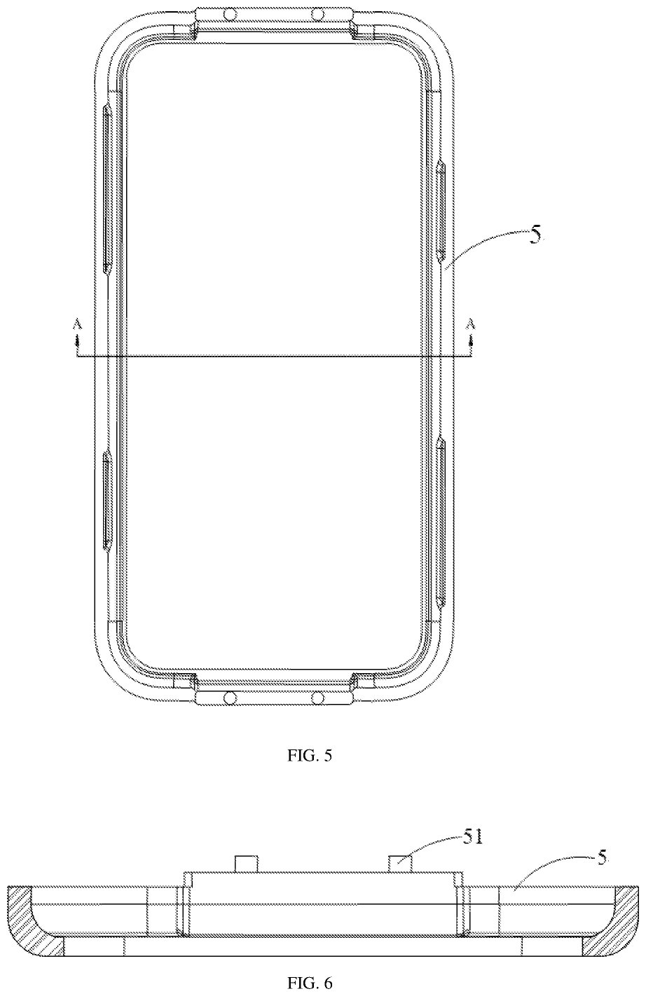

Compared with the prior art, as shown in FIG. 5 and FIG. 6, in the embodiment of the present application, the electronic product to be applied is placed into the positioning frame 5, the positioning lug 11 is positioned and matched with the positioning post 51 on the positioning frame 5 to achieve positioning, the positioning accuracy is high; in addition, the first part 31 is torn off by the first lug 311, and the second part 32 is torn off by the second lug 321, so that the first part 31 and the second part 32 are independent from each other during the tearing process, and the screen protector does not move during the applying process, thereby the applying efficiency is improved.

Preferably, the step of cleaning the screen of the electronic product to be applied further including:

wiping the screen of the electronic product to be applied with an alcohol;

wiping the screen of the electronic product to be applied with a non-woven fabric.

In which, the alcohol bag can eliminate bacteria and other visible dirt on the screen surface. The non-woven fabric can further remove the dirt on the screen surface and dry the alcohol on the screen surface to prevent the alcohol from damaging the screen surface for staying a long time.

Preferably, the step of tearing the first part 31 via the first lug 311 including:

uncovering the first part 31, and then pulling the first lug 311 to tear off an end of the first part 31 adjacent to the second part 32 such that the end of the first part 31 adjacent to the second part 32 is separated from the hydrogel film 2, herein, the portion of the hydrogel film 2 according to the first part 31 can be abutted on the screen to realize the applying process of the hydrogel film 2 and the screen of the electronic product. In the embodiment, the first part 31 is uncovered upward such that the first part 31 is at an angle of 90 degrees with the screen of the electronic product to be applied, thus, the first part 31 can be quickly scraped by a scraping card, and the applying efficiency is improved. In addition, in the embodiment, the first part 31 and the screen of the electronic product to be applied may be disposed at other angles, which is not limited herein.

Preferably, the step of tearing the second part 32 via the second lug 321 including:

uncovering the second part 32, and then pulling the second lug 321 to tear off an end of the second part 32 adjacent to the first part 31 such that the end of the second part 32 adjacent to the first part 31 is separated from the hydrogel film 2, herein, the portion of the hydrogel film 2 corresponding to the second part 32 can be abutted on the screen to realize the applying process of the hydrogel film 2 and the screen of the electronic product. In the embodiment, the second part 32 is uncovered upward such that the second part 32 is at an angle of 90 degrees with the screen of the electronic product to be applied, thus, the second part 32 can be quickly scraped by a scraping card, and the applying efficiency is improved. In addition, in the embodiment, the second part 32 and the screen of the electronic product to be applied may be disposed at other angles, which is not limited herein.

Preferably, in the embodiment, in the above steps S05 and S07, the bottom of the scraping card is placed obliquely relative to the screen, and the initial position of the scraping card is located on the die-cutting line 33. Thus, it is convenient to push the scraping card from the end of the first part 31 adjacent to the second part 32 toward the end away from the second part 32 until the portion of the hydrogel film 2 corresponding to the first part sticks to the plane portion of the screen; and it is also convenient to push the scraping card from the end of the second part 32 adjacent to the first part 31 toward the end away from the first part 31 until the portion of the hydrogel film 2 corresponding to the second part sticks to the plane portion of the screen, thereby finally the hydrogel film is adhered to the screen of the electronic product.

Preferably, the oblique angle between the bottom of the scraping card and the screen ranges from 45 to 60 degrees. Specifically, the angle may be 45°, 50°, 55° 60°, etc., and in the embodiment, the angle is 60°, thus the scraping card is prevented from damaging the screen during the process of the scraping card being pushed. In addition, in the embodiment, the above angle may also be other angles, which is not limited herein.

The aforementioned embodiments are only preferred embodiments of the present invention, and should not be regarded as being limitation to the present invention. Any modification, equivalent replacement, improvement, and so on, which are made within the spirit and the principle of the present invention, should be included in the protection scope of the present application.

What is claimed is:

1. A screen protector, comprising: a release film, a hydrogel film, a silicone protective film, and a release liner sequentially stacked, wherein an edge of the release film is provided with positioning lugs configured for positioning, the silicone protective film is provided with a die-cutting line dividing the silicone protective film into a first part and a second part, wherein an edge of the first part protrudes outwards to form a first lug configured for tearing off the first part, and an edge of the second part protrudes outwards to form a second lug configured for tearing off the second part.

2. The screen protector of claim 1, wherein a top of the first part protrudes outwards to form the first lug, and a bottom of the second part protrudes outwards to form the second lug.

3. The screen protector of claim 2, wherein the release liner corresponding to the position of the first lug protrudes outwards to form a third lug, the release liner corresponding to the position of the second lug protrudes outwards to form a fourth lug.

4. The screen protector of claim 1, wherein the number of the positioning lugs is two, and the two positioning lugs are respectively disposed at opposite ends of the release film, and each of the positioning lugs is provided with at least one positioning hole for positioning.

5. The screen protector of claim 2, wherein the number of the positioning lugs is two, and the two positioning lugs are respectively disposed at opposite ends of the release film, and each of the positioning lugs is provided with at least one positioning hole for positioning.

6. The screen protector of claim 3, wherein the number of the positioning lugs is two, and the two positioning lugs are respectively disposed at opposite ends of the release film, and each of the positioning lugs is provided with at least one positioning hole for positioning.

7. A method for applying the screen protector of claim 1, comprising:
S01, cleaning a screen of an electronic product to be applied, and placing the electronic product to be applied into a positioning frame;
S02, tearing off the release liner;
S03, applying the silicone protective film to the screen of the electronic product to be applied by positioning the positioning lugs with the positioning frame;
S04, tearing off the first part via the first lug of the first part;
S05, using a scraping card to forcefully scrape the first part until a portion of the hydrogel film corresponding to the first part sticks to a planar portion of the screen;
S06, tearing off the second part via the second lug of the second part, and using the scraping card to forcefully scrape the second part until a portion of the hydrogel film corresponding to the second part sticks to a planar portion of the screen;
S07, using the scraping card to scrape outwardly along a curved edge of the screen until two lateral edges of the hydrogel film stick to two lateral edges of the screen;
S08, tearing off the release film via the positioning lug of the release film, and smoothing two lateral edges of the screen.

8. The method of claim 7, wherein the step of cleaning the screen of the electronic product to be applied further comprising:
wiping the screen of the electronic product to be applied with an alcohol;
wiping the screen of the electronic product to be applied with a non-woven fabric.

9. The method of claim 7, wherein the step of tearing off the first part via the first lug of the first part further comprising:
uncovering the first part, and then pulling the first lug to tear off an end of the first part adjacent to the second part such that said end of the first part adjacent to the second part is separated from the hydrogel film, and abutting the portion of hydrogel film corresponding to the first part onto the screen.

10. The method of claim 7, wherein the step of tearing off the second part via the second lug of the second part further comprising:
uncovering the second part, and then pulling the second lug to tear off an end of the second part adjacent to the first part such that the end of the second part adjacent to the first part is separated from the hydrogel film, and abutting the portion of hydrogel film corresponding to the second part onto the screen.

11. The method of claim 7, wherein in the step S05 and the step S07, a bottom of the scraping card is placed obliquely relative to the screen, and an initial position of the scraping card during the scraping is located on the die-cutting line.

12. The method of claim 11, wherein an oblique angle between the bottom of the scraping card and the screen is in the rang of 45° to 60°.
